(19) United States
(12) Patent Application Publication
(10) Pub. No.: US 2025/0028893 A1
(43) Pub. Date: Jan. 23, 2025

(54) OPTIMIZED CELL LAYOUT

(71) Applicant: Taiwan Semiconductor Manufacturing Co., Ltd., Hsinchu (TW)

(72) Inventors: Bo-Huan HSIN, Taichung City (TW); Ying-Han CHIOU, Tainan City (TW); Shih-Cheng CHANG, Tainan City (TW)

(73) Assignee: Taiwan Semiconductor Manufacturing Co., Ltd., Hsinchu (TW)

(21) Appl. No.: 18/356,408

(22) Filed: Jul. 21, 2023

(51) Int. Cl. G06F 30/392

(52) U.S. Cl. CPC G06F 30/392

(57) ABSTRACT

The present disclosure describes an example layout and method for cell placement in an integrated circuit (IC) layout design. The layout includes a first semiconductor structure having a first channel with a first channel width and a second semiconductor structure having a second channel with a second channel width different from the first channel width. The first and second channels can be in contact with each other. The method includes disposing a first diffusion region in a layout area and disposing a second diffusion region in the layout area. The first diffusion region can have a first diffusion region width and the second diffusion region can have a second diffusion region width different from the first diffusion region width.

### BACKGROUND

An electronic design automation (EDA) tool can be used for an integrated circuit (IC) design flow. For example, the EDA tool can be used to place layout cells (e.g., cells that implement logic or other electronic functions) in an IC layout design. As technology increases and the demand for efficient ICs grow, EDA tools become increasingly important to aid in the design of complex IC layout designs.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is an illustration of a layout for a circuit implementation, according to some embodiments of the present disclosure.

FIG. 2A is an illustration of another layout for a circuit implementation, according to some embodiments of the present disclosure.

FIG. 2B is a cross-sectional illustration of a layout for a circuit implementation, according to some embodiments of the present disclosure

FIG. 3 is an illustration of yet another layout for a circuit implementation, according to some embodiments of the present disclosure.

FIG. 4 is a flow chart of a layout method, according to some embodiments of the present disclosure.

FIG. 5 is an illustration of still another layout for a circuit implementation, according to some embodiments of the present disclosure.

FIG. 6 is an illustration of an example computer system in which various embodiments of the present disclosure can be implemented, according to some embodiments of the present disclosure.

FIG. 7 is an illustration an integrated circuit manufacturing system and associated integrated circuit manufacturing flow, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. In addition, the present disclosure repeats reference numerals and/or letters in the various examples. This repetition is for the purpose of simplicity and clarity and, unless indicated otherwise, does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

As used herein, the meaning of “a,” “an,” and “the” includes singular and plural references unless the context clearly dictates otherwise.

The term “and/or” when used in a list of two or more items, means that any one of the listed items can be employed by itself or in combination with any one or more of the listed items. For example, the expression “A and/or B” is intended to mean either or both of A and B, i.e., A alone, B alone, or A and B in combination. The expression “A, B and/or C” is intended to mean A alone, B alone, C alone, A and B in combination, A and C in combination, B and C in combination or A, B, and C in combination.

The following disclosure relates to optimizing layout cells in an integrated circuit (IC) layout design. Electronic design automation (EDA) tools can be used to place layout cells and dummy fill structures in the integrated circuit layout design. The layout cells can be associated with circuits or devices that perform particular functions in the integrated circuit, such as a logic function, an analog function, and other suitable functions. The dummy fill structures have no particular function and can be inserted by the electronic design automation tool to facilitate downstream processing, such as a chemical mechanical polishing (CMP) process. As technology increases and the demand for mixed device and circuit structures grow, an increasing number of layout cells, as well as the ability to provide a diverse array of layout cells, is required to fit in smaller integrated circuit layout designs, thus creating challenges for integrated circuit manufacturers. Embodiments of the present disclosure address this challenge, among others, by introducing a diverse array of layout cells with different configurations and/or functions to optimize a circuit implementation. Additionally, providing a diverse array of layout cells can minimize the insertion of dummy fill structures by the EDA tool.

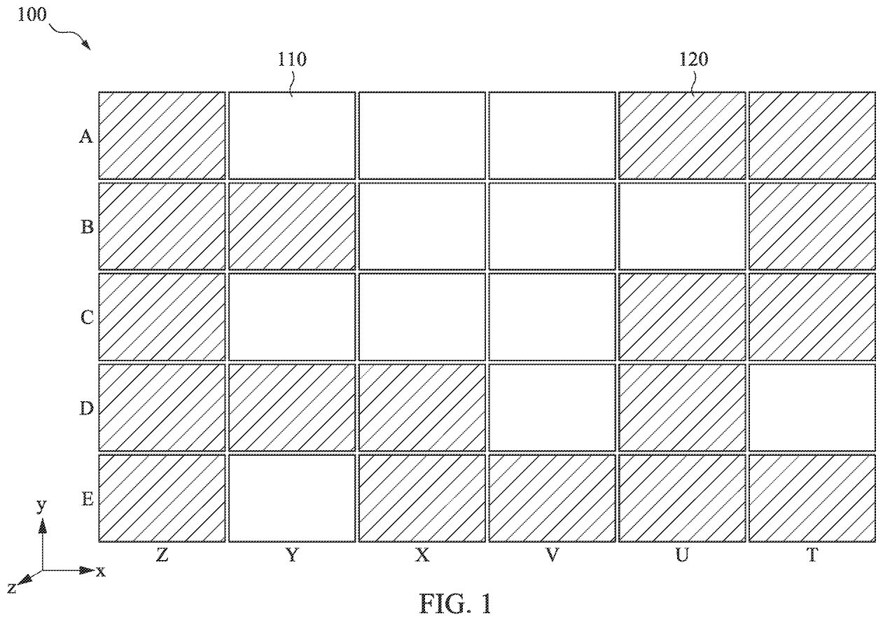

FIG. 1 is an illustration of a layout 100 for a circuit implementation, according to some embodiments of the present disclosure. The layout 100 can include a high speed cell 110 (gray shaded rectangles) and a passive cell 120 (dark shaded rectangles). In some embodiments of the present disclosure, the rows and columns shown in FIG. 1 are individual tracks of an IC layout. As used herein, a track refers to a linear array of layout cells (for example, layout cells along an x-axis of the layout, along a y-axis of the layout, or along a z-axis of a layout). For example, rows A, B, C, D, and E, and columns Z, Y, X, V, U, and T each represent an individual track according to some embodiments. As shown in FIG. 1, each track can include at least two different cell types. In some embodiments of the present disclosure, the cell types can be a high speed cell 110 or a passive cell 120.

In some embodiments of the present disclosure, FIG. 1 shows multiple layout cells (for example, high speed cells 110 and passive cells 120) that directly abut one another. In some embodiments, the direct abutment arrangement shown in FIG. 1 shows layout cells (for example, high speed cells 110 and passive cells 120) abutting one another in the same orientation along the horizontal and vertical directions (e.g., x- and y-directions, respectively). For example, the right side of the passive cell occupying row track A and column track Z is abutted to the left side of the high speed cell occupying row track A and column track Y, and the bottom side of the passive cell occupying row track A and column track Z is abutted to the top side of the passive cell occupying row track B and column track Z.

The layout 100 can include multiple semiconductor device cells (for example, high speed cells 110 and passive cells 120), according to some embodiments. In some embodiments, each of the semiconductor device cells can be a layout representation of a single transistor device, such as an n-type field effect transistor (FET) device or a p-type FET device. The FET devices (e.g., n-type FET device and p-type FET device) can be planar metal-oxide-semiconductor FET devices, fin type field effect transistor (finFET) devices, gate all around FET devices, any other suitable type of FET devices, or any combinations thereof. In some embodiments, each of the semiconductor device cells can be a layout representation of one or more transistor devices, such as a logic device (e.g., inverter logic device, NAND logic device, NOR logic device, and XOR logic device). Further details on and embodiments of the layout 100 and each of the semiconductor device cells are described below.

In some embodiments of the present disclosure, the layout 100 can include any desired quantity of high speed cells 110 or passive cells 120, depending on the circuit and/or system. While some examples can depict alternating high speed cells 110 and passive cells 120, the high speed cells 110 and the passive cells 120 need not be disposed in an alternating configuration. For example, a first high speed cell 110 can neighbor a second high speed cell 110, and so on. Similarly, a first passive cell 120 can neighbor a second passive cell 120, and so on.

In some embodiments of the present disclosure, a high speed cell 110 can include a high performance computing (HPC) product. For example, the high performance computing product can be a fin type field effect transistor, a gate all around transistor, a nano sheet, a two dimensional material device, a back end of the line (BEOL) device, a high performance memory, an accelerator, a backplane, a graphics engine, a level-shifter circuit, an inverter logic device, a NAND logic device, a three dimensional NAND logic device, an n-type metal oxide silicon (NMOS) device, a p-type metal oxide silicon (PMOS) device, a NOR logic device, an XOR logic device, any other suitable analog/logic devices, or a combination thereof. In some embodiments of the present disclosure, the high speed cell 110 can be a cell that consumes more energy when compared to the passive cells 120.

In some embodiments of the present disclosure, the passive cells 120 can include a resistor, a capacitor, a diode (for example, a Zener diode, a light emitting diode, a diode bridge circuit, a rectifier circuit, or a combination thereof), an inductor, a crystal, an oscillator, a relay, a switch, a connector, an amplifier circuit, a memory, a filter, or any combination thereof.

The layout 100 can include one or more semiconductor device cells that include an analog function, a logic function, or a combination thereof. For example, a circuit implementation in the layout 100 can include a level-shifter circuit, an amplifier circuit, a passive device (e.g., resistor and capacitor), an inverter logic device, a NAND logic device, a NOR logic device, an XOR logic device, any other suitable analog/logic devices, or a combination thereof. In some embodiments, through the connection of multiple semiconductor device cells (e.g., through one or more interconnects), the circuit implementation can be achieved. Further details and embodiments on the connection of multiple semiconductor device cells to achieve a particular analog and/or logic circuit function are described below.

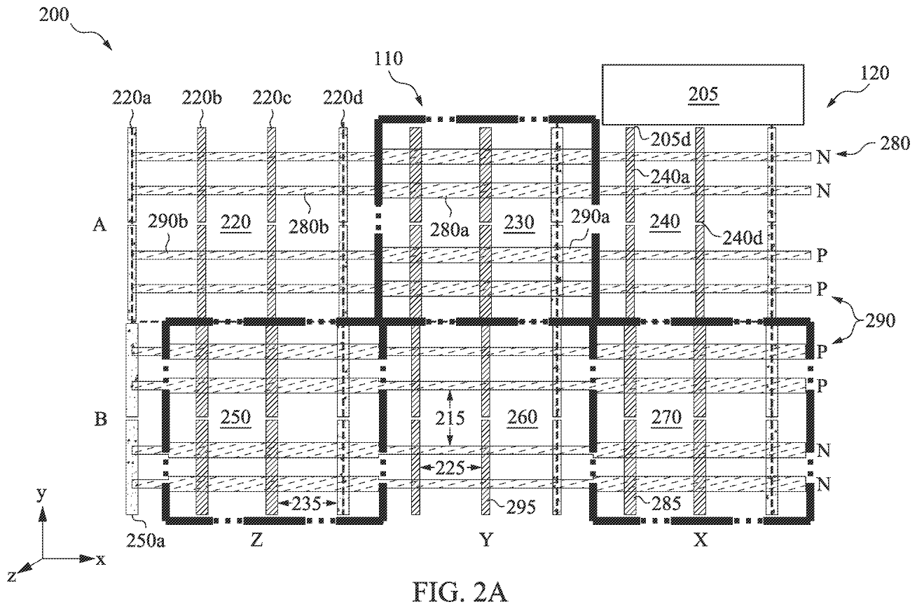

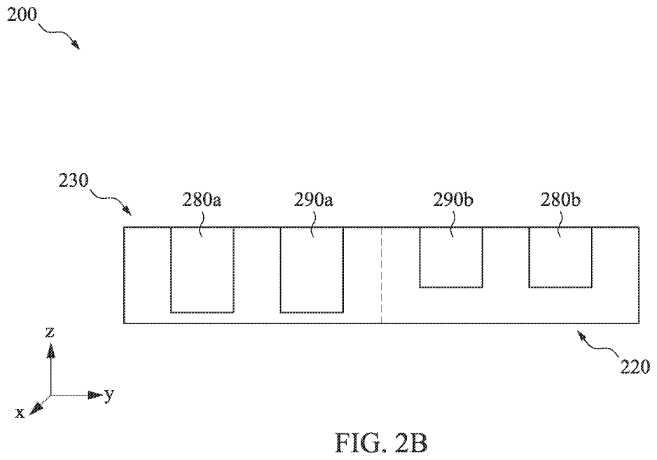

FIG. 2A is an illustration of a layout for a circuit implementation 200, according to some embodiments. In some embodiments, the circuit implementation 200 can be used in the layout 100 of FIG. 1 and can represent, for example, a plurality of FET devices, such as a plurality of n-type FET devices and a plurality of p-type FET devices that share a common gate structure, for example, the gate structure 220a shown in FIG. 2A. In some embodiments of the present disclosure, the gate structures include a gate electrode and a gate dielectric. In some embodiments of the present disclosure, the gate electrode can include a conductive fill feature. For example, the conductive fill feature can be any of cobalt (Co), titanium (Ti), titanium nitride (TIN), tungsten (W), copper (Cu), aluminum (Al), gallium (Ga) zinc (Zn), ruthenium (Ru), molybdenum (Mo), indium tin oxide (ITO), or a metal compound. In some embodiments of the present disclosure, the gate dielectric can be any of hafnium oxide (HfO), hafnium dioxide (HfO₂), silicon dioxide (SiO₂), tantalum oxide (TaO), tantalum pentoxide (Ta₂O₅), alumina (Al₂O₃), silicon nitride (SiN), zirconium oxide (ZrO), zirconium dioxide (ZrO₂), titanium oxide (TiO), or lanthanum (La).

In some embodiments of the present disclosure, the gate electrode can be electrically coupled to a slot type device input/output port. For example, a slot type port 205 can be employed to electrically and/or communicatively couple one system to another. The slot type port 205 can be electrically coupled to a SiGe layer of the semiconductor device through a silicide layer. In some embodiments of the present disclosure, the slot type port 205 can be connected to a semiconductor device epitaxially grown Si layer through a silicide layer. In some embodiments of the present disclosure, the layout 100 depicted in FIG. 1 can be an individual system. Accordingly, the slot type port 205 provides the ability to connect a system to another system, or a plurality of systems. In some embodiments, the slot type port 205 and the gate electrode are up to about 100 nanometers (nm) apart (for example, the gate electrode 240a and the slot type port 205 are separated by a distance 205d of about 100 nm, about 90 nm, about 80 nm, about 70 nm, about 60 nm, or about 50 nm.

In some embodiments of the present disclosure, the gate electrode can have a substantially rectangular shaped terminal. In some embodiments, the rectangular shaped terminal can facilitate the electrical coupling between the gate electrode and the slot type port. In some embodiments, the substantially rectangular terminal facilitates connection from a first gate electrode to a second gate electrode, for example, to electrically couple a first cell to a second cell. In some embodiments, the substantially rectangular terminal is used to connect a high performance semiconductor device gate structure to a passive semiconductor gate structure. Likewise, the substantially rectangular terminal can be used to connect two passive semiconductor device gate structures and/or the substantially rectangular terminal can be used to connect two high performance semiconductor device gate structures.

In some embodiments of the present disclosure, a distance between a first gate electrode terminal and a second gate electrode terminal is less than or equal to 100 nm. For example, the first gate electrode terminal is separated from the second gate electrode terminal by a distance 240d of about 100 nm, about 90 nm, about 80 nm, about 70 nm, about 60 nm, or about 50 nm.

Referring to FIG. 2A, the circuit implementation 200 includes high speed cells 110 and passive cells 120 can simultaneously occupy a common device track (for example, A-E or Z-T of FIG. 1). As shown in FIG. 2A, device track A includes a first passive cell 220, a high speed cell 230, and a second passive cell 240. Likewise, track B includes a high speed cell 250, a passive cell 260, and a second high speed cell 270. In some embodiments of the present disclosure, track Z includes the passive cell 220 and the high speed cell 250, track Y includes the high speed cell 230 and the passive cell 260, and track X includes the passive cell 240 and the high speed cell 270.

Also shown in FIG. 2A are n-type channels 280 and p-type channels 290. In some embodiments of the present disclosure, the channels can occupy the horizontal tracks (for example, tracks A-E depicted in FIG. 1). In some embodiments, the channels can occupy the vertical channels (for example, tracks Z-T depicted in FIG. 1).

In some embodiments of the present disclosure, a width of the n-type channels 280 and the p-type channels 290 can be determined based on diffusion design rules associated with a technology node and/or a semiconductor manufacturing process for the overall layout (e.g., the layout 100 depicted in FIG. 1). For example, the width can be determined based on design rules for the type of device intended to occupy a particular cell (for example, a high performance semiconductor device occupying a high speed cell 110 or a passive semiconductor device occupying a passive cell 120).

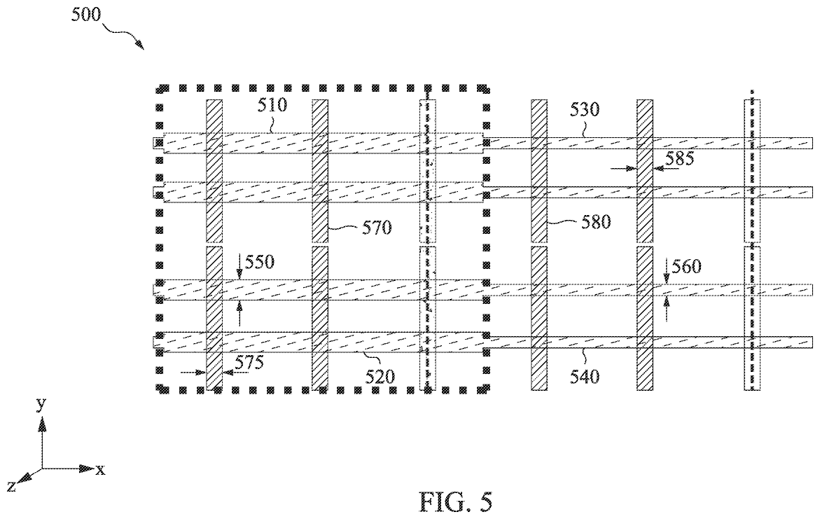

In some embodiments of the present disclosure, the n-type channels 280 and the p-type channels 290 can have varying channel widths to accommodate the type of device occupying a particular cell. For example, a first semiconductor structure 230 can have a first channel width 550 (see FIG. 5), and a second semiconductor structure 220 can have second channel width 560. The first channel width 550 can be greater than the second channel width 560, in some examples. In some embodiments of the present disclosure, the first semiconductor structure 230 (for example, a high performance semiconductor device occupying the high speed cells 110) can have n-type channels 280 and p-type channels 290 having a greater width than the n-type channels 280 and the p-type channels 290 associated with the second semiconductor structure 220 (for example, a passive semiconductor device occupying the passive cells 120).

As shown in FIG. 2A, the first semiconductor structure (for example, a high speed cell) 230 includes n-type channels 280a and p-type channels 290a running along the x-axis having widths greater than the n-type channels 280b and the p-type channels 290b associated with the second semiconductor structure (for example, a passive cell) 220. In FIG. 2A, the channels run along the x-axis and the channel width is varied in the y-axis direction. In some embodiments of the present disclosure, the wider n-type channels 280a and the wider p-type channels 290a can accommodate a greater amount of current that is consumed by the high performance semiconductor devices occupying the high speed cells 110. Similarly, the wider n-type channels 280a and the wider p-type channels 290a can be configured to provide the greater amount of current to the high performance semiconductor devices occupying the high speed cells 110.

In some embodiments, a height along the z-axis of the n-type channels 280 and the p-type channels 290 can be determined based on diffusion design rules associated with a technology node and/or a semiconductor manufacturing process for the overall layout (e.g., the layout 100 depicted in FIG. 1). In FIG. 2A, the channels run along the x-axis and the channel height is varied in the z-axis direction. For example, the z-axis height (or depth) can be determined based on design rules for a relative width and spacing of a particular diffusion layer. A minimum value for the height can be based on a width of the diffusion layer (e.g., the x-axis width of the n-type channels 280a and p-type channels 290a associated with the high speed cells 110 the n-type channels 280b and the p-type channels 290b associated with the passive cells 120).

In some embodiments of the present disclosure, the high speed cell 230 includes n-type channels 280a and p-type channels 290a having z-axis channel heights greater than the n-type channels 280b and the p-type channels 290b associated with the passive cell 220, as illustrated in FIG. 2B. In some embodiments of the present disclosure, the greater channel height of the n-type channels 280a and the greater channel height of the p-type channels 290a can accommodate a greater amount of current that is consumed by the high performance semiconductor devices occupying the high speed cells 110. Similarly, the greater channel height of the n-type channels 280a and the greater channel height of the p-type channels 290a can be configured to provide the greater amount of current to the high performance semiconductor devices occupying the high speed cells 110.

In FIG. 2A, high performance semiconductor device gate structures 285 and passive semiconductor device gate structures 295 are also shown. In some embodiments of the present disclosure, the gate structures can occupy the y-axis channels (for example, tracks Z-T depicted in FIG. 1). In some embodiments of the present disclosure, the gate structures can occupy the x-axis tracks (for example, tracks A-E depicted in FIG. 1).

In some embodiments of the present disclosure, the high performance semiconductor device gate structures 285 and the passive semiconductor device gate structures 295 can have varying gate widths to accommodate the type of device occupying a particular cell. In FIG. 2A, the gate structures run along the y-axis and the gate width is varied in the x-axis direction. For example, the high speed semiconductor structure 285 can have a first gate width, and the passive semiconductor structure 295 can have second gate width. In some embodiments, the first gate width can be greater than the second gate width. In some embodiments, the high performance semiconductor device occupying the high speed cells 110 can have high performance semiconductor device gate structures 285 having a greater width than that of the passive semiconductor device gate structures 295.

In some embodiments, a pitch 215 of the n-type channels 280 and the p-type channels 290 can be determined based on polysilicon design rules associated with a technology node and/or a semiconductor manufacturing process for the overall layout (e.g., the layout 100 depicted in FIG. 1). For example, the pitch 215 can be determined based on design rules for a relative width and spacing of a particular polysilicon layer, for example, a sacrificial layer or a dummy gate layer.

In some embodiments of the present disclosure, the high performance semiconductor device gate structures 285 and the passive semiconductor device gate structures 295 can have varying gate pitches 225 to accommodate the type of device occupying a particular cell. For example, the high speed semiconductor structure can have a first gate pitch 235, and the passive semiconductor structure can have second gate pitch 225. In some embodiments, the first gate pitch 235 can be greater than the second gate pitch 225. In some embodiments, the high performance semiconductor device occupying the high speed cells 110 can have high performance semiconductor device gate structures 285 having a greater pitch 235 than the passive semiconductor device gate structures 295.

Further shown in FIG. 2A, the high performance semiconductor device gate structures 285 and the passive semiconductor device gate structures 295 can connect from cell to cell. For example, the gate structure of a first cell can be electrically coupled to the gate structure of a second cell. In some embodiments of the present disclosure, the high performance semiconductor device gate structures 285 of high speed cell 270 in track B can be electrically coupled to the passive semiconductor device gate structures 295 of passive cell 240 occupying track A.

In FIG. 2A, each cell in the circuit implementation 200 can have a plurality of gate structures therein. For example, the passive cell 220 includes 4 separate gate structures, 220a, 220b, 220c, and 220d. In some embodiments of the present disclosure, any of the gate structures 220a, 220b, 220c, or 220d can be a dummy gate. Also, any one of gate structure 220a, 220b, 220c, or 220d can be electrically coupled to a gate structure of another cell, for example, gate structure 250a of the high speed cell 250.

In some embodiments of the present disclosure, one or more dummy fill structures are inserted in areas of the layout 100 that are not occupied by the high performance semiconductor devices or the passive semiconductor devices. The dummy fill structures have no particular function and can be inserted by the electronic design automation tool to facilitate in layer planarity during the semiconductor manufacturing process, such as during a chemical mechanical polishing process. In some embodiments, the regions in which the electronic design automation tool can insert dummy fill structures are limited to unoccupied layout 100 cell regions.

In some embodiments of the present disclosure, the dummy fill structures can have varying gate widths. For example, the dummy fill structure can have a gate width substantially equal to the first gate width (for example, the gate width of any of the gate structures 220a, 220b, 220c, or 220d of the high speed semiconductor structure). In some embodiments, the dummy fill structure can have a gate width substantially equal to the second gate width (for example, second gate width corresponding to the passive semiconductor structure).

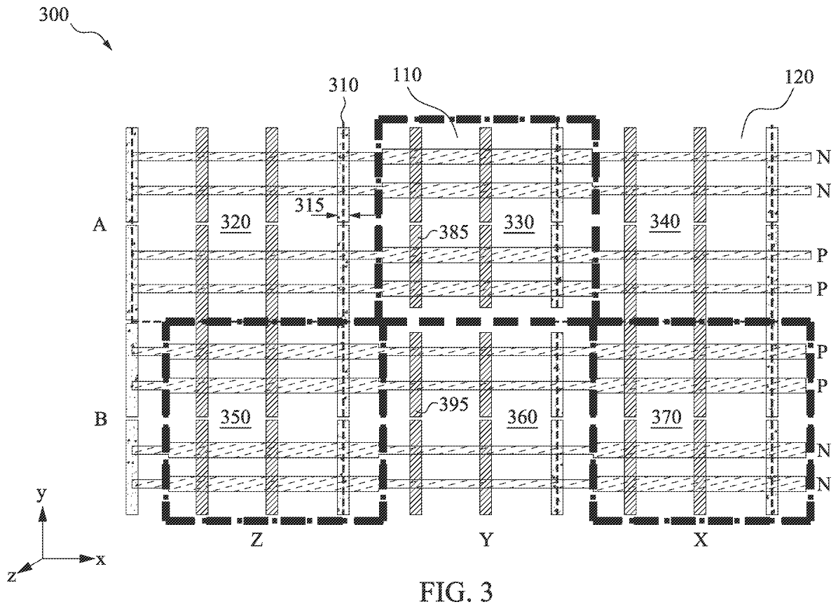

In some embodiments of the present disclosure, FIG. 3 shows a layout for a circuit implementation 300. In some embodiments of the present disclosure, the high performance semiconductor device gate structures 385 and the passive semiconductor device gate structures 395 can be isolated from cell to cell. For example, the gate structure of a first cell can be electrically decoupled from the gate structure of a second cell. In some embodiments of the present disclosure, the high performance semiconductor device gate structures 385 of a first semiconductor device cell (for example, a high speed cell) 330 in track A can be electrically decoupled from the passive semiconductor device gate structures 395 of a second semiconductor device cell (for example, a passive cell) 360 occupying track B.

In some embodiments of the present disclosure, the cells (for example, the high speed cells 110 or the passive cells 120) can be electrically coupled to a reference voltage. For example, at least one first semiconductor device gate (for example, at least one high performance semiconductor device) is coupled to a reference voltage (V) in a range from about 0.5 V to about 3 V, according to some embodiments. The reference voltage can be about 0.5 V, about 0.6 V, about 0.7 V, about 0.8 V, about 0.9 V, about 1 V, about 1.1 V, about 1.2 V, about 1.3 V, about 1.4 V, about 1.5 V, about 1.6 V, about 1.7 V, about 1.8 V, about 1.9 V, about 2 V, about 2.1 V, about 2.2 V, about 2.3 V, about 2.4 V, about 2.5 V, about 2.6 V, about 2.7 V, about 2.8 V, about 2.9 V, or about 3 V. In some embodiments, the reference voltage can be a voltage drain (VDD) or a voltage source (VSS). Accordingly, the high performance semiconductor device gate structure 385 can be electrically coupled to the voltage drain, or the high performance semiconductor device gate structure 385 can be electrically coupled to the voltage source. In some embodiments of the present disclosure, a dummy fill structure gate 310 can be electrically coupled to the reference voltage. For example, the dummy fill structure gate 310 can be coupled to the voltage drain, or the dummy fill structure gate 310 can be coupled to the voltage source.

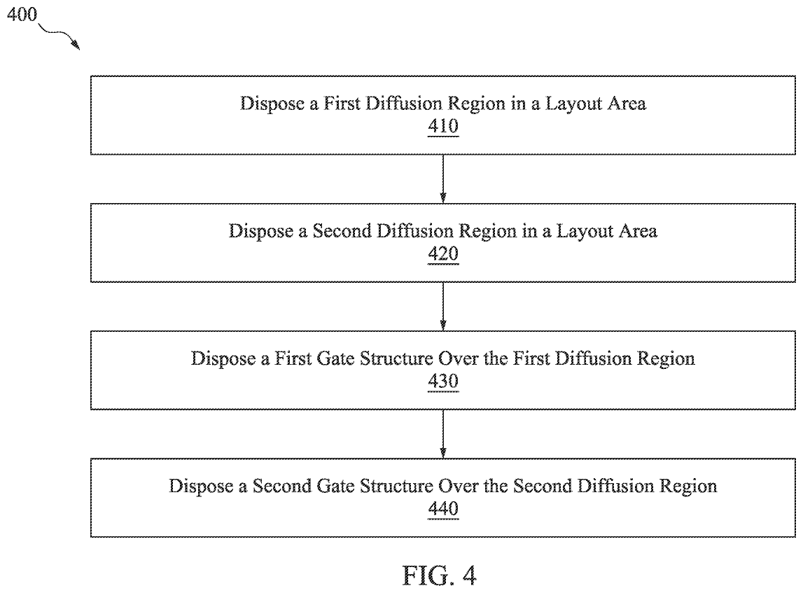

In some embodiments of the present disclosure, a method of providing a mixed cell layout is described. In some embodiments of the present disclosure, FIG. 4 is a flow chart illustration a layout creation method 400. For illustrative purposes, the operations of method 400 will be described with reference to FIGS. 1, 2, 3, and 5. The operations of method 400 can be performed in a different order or not performed depending on specific applications. Further, it is understood that additional operations can be provided before, during, and after method 400, and that other operations may only be briefly described herein.

In operation 410, a first diffusion region is disposed in a chosen layout area (for example, a high speed cell 110 or a passive cell 120 as depicted in FIG. 1). For example, the first diffusion region can be either of the n-type channels 280 or the p-type channels 290 occupying a high speed cell, for example the high speed cell 230, as depicted in FIG. 2A. In some embodiments, a second diffusion region can be either of the n-type channels 280 or the p-type channels 290 occupying a passive cell, for example the passive cell 240, as depicted in FIG. 2A.

In operation 420, a second diffusion region is disposed in a chosen layout area (for example, a high speed cell 110 or a passive cell 120 as depicted in FIG. 1). For example, the first diffusion region can be either of the n-type channels 280 or the p-type channels 290 occupying a high speed cell, for example the high speed cell 230, as depicted in FIG. 2A. In some embodiments, a second diffusion region can be either of the n-type channels 280 or the p-type channels 290 occupying a passive cell, for example the passive cell 240, as depicted in FIG. 2A.

Referring now to FIG. 5, a first diffusion region 510 can be either an n-type channel or a p-type channel having a first channel width 550. Likewise, a second diffusion region 530 can be either an n-type channel or a p-type channel having a second channel width 560. In FIG. 5, the diffusions regions (510, 520, 530, and 540) run along the x-axis and the diffusion region width (550, 560) is varied in the y-axis direction. In some embodiments of the present disclosure, the first channel width 550 of the first diffusion region (510, 520) can be greater than the second channel width 560 of the second diffusion region (530, 540). In some embodiments of the present disclosure, the first channel width 550 can be less than the second channel width 560.

Returning now to FIG. 4, in operation 420, the method 400 can include depositing the second diffusion region 530 such that the first diffusion region 510 is connected to the second diffusion region 530. For example, the first diffusion region 510 can be electrically coupled to the second diffusion region 530. In some embodiments of the present disclosure, the first diffusion region 510 can be an n-type channel of a high speed cell (for example, the high speed cell 110 shown in FIG. 1) and the second diffusion region 530 can be an n-type channel of a passive cell (for example, the passive cell 120 shown in FIG. 1). In some embodiments, the first diffusion region 510 can be a p-type channel of a high speed cell (for example, the high speed cell 110 shown in FIG. 1) and the second diffusion region 530 can be an p-type channel of a passive cell (for example, the passive cell 120 shown in FIG. 1). The first diffusion region 510 can be a charge carrying channel of a high performance semiconductor device, and the second diffusion region 530 can be a charge carrying channel of a passive semiconductor device.

In some embodiments of the present disclosure, in operation 420, depositing the second diffusion region 530 such that the second diffusion region 530 is connected to the first diffusion region 510 can be the basis for creating the circuit tracks (for example, x-axis tracks A-E and/or y-axis tracks Z-T depicted in FIG. 1). For example, connecting at least the first diffusion region 510 to the second diffusion region 530 can create at least a first n-type channel extending through a plurality of cells that are adjacent to each other along a particular track (for example, high speed cells 110 and passive cells 120 disposed in the x-axis track A of FIG. 1).

In some embodiments of the present disclosure, in operation 430, the method includes disposing a first gate structure 570 over the first diffusion region 510. The first gate structure 570 can have a third width 575. In some embodiments of the present invention, the first gate structure 570 and the third width 575 can be a gate structure and a gate width of a high performance semiconductor device occupying a high speed cell 110, as in the example of FIG. 1. In some embodiments of the present disclosure, in operation 440, the method also includes disposing a second gate structure 580 over the second diffusion region 530. The second gate structure 580 can have a fourth width 585. In some embodiments, the second gate structure 580 and the fourth width 585 can be a gate structure and a gate width of a passive semiconductor device occupying a passive cell 120, as depicted in FIG. 1.

Likewise, certain layout cells can have a dummy gate 310 having a dummy gate width 315 as shown in FIG. 3. In some embodiments of the present disclosure, the dummy gate width 315 can be a fifth width distinct from the third width 575 and/or the fourth width 585 shown in FIG. 5. In some embodiments, the dummy gate width 315 can be substantially similar to the third width 575 and/or the fourth width 585.

In some embodiments of the present disclosure, in operation 440, the second gate structure 395 (as shown in FIG. 3) can be deposited such that the second gate structure 395 is connected to the first gate structure 385. In some embodiments of the present disclosure, the method can include decoupling the first gate structure 385 from the second gate structure 395. For example, a first gate structure of a first cell can be coupled to a first gate structure of a second cell, and a second gate structure of the first cell can be decoupled from a second gate structure of the second cell. For example, the high performance semiconductor device occupying the high speed cell 330 can have the gate structure 385 decoupled from the gate structure 395 of the passive cell 360. The gate structure decoupling can be performed as desired during circuit implementation.

In some embodiments of the present disclosure, at least one first gate structure or at least one second gate structure can be electrically coupled to a reference voltage. For example, at least one first gate structure can be electrically coupled to a voltage drain or a voltage source. Likewise, at least one second gate structure can be electrically coupled to a voltage drain or a voltage source. In some embodiments of the present disclosure, the method can further include disposing dummy fill structures in the layout area. For example, a dummy fill structure can be disposed over the first diffusion region 510 and/or the second diffusion region 530.

A benefit, among others, of the method 400 and the embodiments described herein is the optimization of energy consumption and clock speed in the integrated circuit layout design. This optimization is advantageous for at least two reasons. First, by manufacturing the layout cells based on mixed layout cells (for example, mixing high speed cells and passive cells on a single diffusion region track), the efficiency of the circuit increases because passive cells can exploit greater amounts of current supplied to high speed cells without adverse effects to the performance of the high speed cells. As noted previously, the dummy fill structures can have no electrical or electronic function, but can serve to facilitate certain downstream processing, such as chemical mechanical polishing.

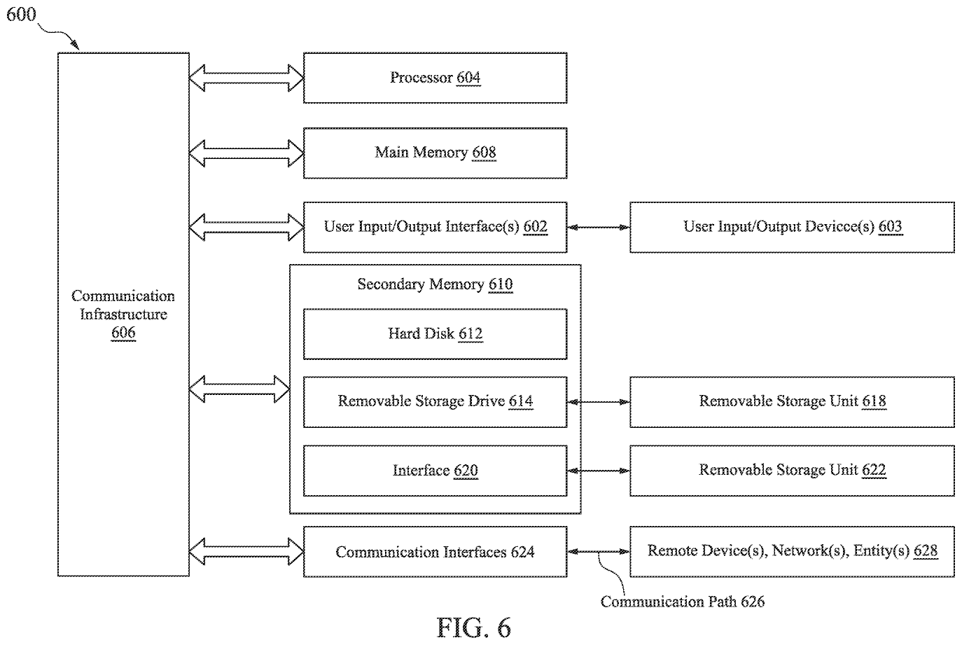

FIG. 6 is an illustration of an example computer system 600 in which various embodiments of the present disclosure can be implemented, according to some embodiments. The computer system 600 can be any well-known computer capable of performing the functions and operations described herein. For example, and without limitation, the computer system 600 can be capable of indicating layout cell types and connecting layout cell types in the layout cells to provide circuit implementations in an integrated circuit layout design using, for example, an electronics design automation tool. The computer system 600 can be used, for example, to execute one or more operations in method 400, which describes an example method for semiconductor device cell layout.

The computer system 600 includes one or more processors (also called central processing units, or CPUs), such as a processor 604. The processor 604 is connected to a communication infrastructure or bus 606. The computer system 600 also includes input/output device(s) 603, such as monitors, keyboards, pointing devices, etc., that communicate with communication infrastructure or the bus 606 through input/output interface(s) 602. An electronic design automation tool can receive instructions to implement functions and operations described herein—e.g., method 400 of FIG. 4—via the input/output device(s) 603. The computer system 600 also includes a main or primary memory 608, such as random access memory (RAM). A main memory 608 can include one or more levels of cache. The main memory 608 has stored therein control logic (e.g., computer software) and/or data. In some embodiments, the control logic (e.g., computer software) and/or data can include one or more of the operations described above with respect to method 400 of FIG. 4.

The computer system 600 can also include one or more secondary storage devices or memory 610. The secondary memory 610 can include, for example, a hard disk drive 612 and/or a removable storage device or drive 614. The removable storage drive 614 can be a floppy disk drive, a magnetic tape drive, a compact disk drive, an optical storage device, tape backup device, and/or any other storage device/drive.

The removable storage drive 614 can interact with a removable storage unit 618. The removable storage unit 618 includes a computer usable or readable storage device having stored thereon computer software (control logic) and/or data. The removable storage unit 618 can be a floppy disk, magnetic tape, compact disk, DVD, optical storage disk, and/any other computer data storage device. The removable storage drive 614 reads from and/or writes to the removable storage unit 618 in a well-known manner.

According to some embodiments, the secondary memory 610 can include other means, instrumentalities or other approaches for allowing computer programs and/or other instructions and/or data to be accessed by the computer system 600. Such means, instrumentalities or other approaches can include, for example, a removable storage unit 622 and an interface 620. Examples of the removable storage unit 622 and the interface 620 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 610, the removable storage unit 618, and/or the removable storage unit 622 can include one or more of the operations described above with respect to method 400 of FIG. 4.

The computer system 600 can further include a communication or network interface 624. The communication interface 624 enables the computer system 600 to communicate and interact with any combination of remote devices, remote networks, remote entities, etc. (individually and collectively referenced by reference number 628). For example, the communication interface 624 can allow the computer system 600 to communicate with remote devices 628 over a communications path 626, which can be wired and/or wireless, and which can include any combination of LANs, WANs, the Internet, etc. Control logic and/or data can be transmitted to and from the computer system 600 via the communication path 626.

The operations in the preceding embodiments can be implemented in a wide variety of configurations and architectures. Therefore, some or all of the operations in the preceding embodiments—e.g., method 400 of FIG. 4—can be performed in hardware, in software or both. In some embodiments, a tangible apparatus or article of manufacture comprising a tangible computer useable or readable medium having control logic (software) stored thereon is also referred to herein as a computer program product or program storage device. This includes, but is not limited to, the computer system 600, the main memory 608, the secondary memory 610, and the removable storage units 618 and 622, as well as tangible articles of manufacture embodying any combination of the foregoing. Such control logic, when executed by one or more data processing devices (such as the computer system 600), causes such data processing devices to operate as described herein.

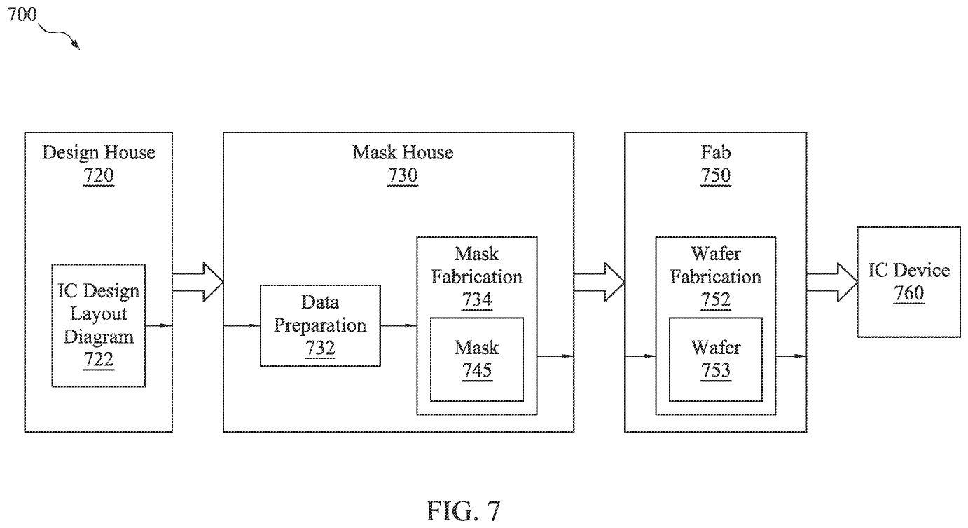

FIG. 7 is an illustration of an integrated circuit manufacturing system 2000 and associated integrated circuit manufacturing flow, according to some embodiments. In some embodiments, the layout cells described herein—e.g., layout 100 and the high speed cell 110 and/or the passive cell 120 of FIG. 1—can be fabricated using the integrated circuit manufacturing system 700.

The integrated circuit manufacturing system 700 includes a design house 720, a mask house 730, and an integrated circuit manufacturer/fabricator (“fab”) 750—each of which interacts with one another in the design, development, and manufacturing cycles and/or services related to manufacturing an integrated circuit device 760. The design house 720, the mask house 730, and the fab 750 are connected by a communications network. In some embodiments, the communications network is a single network. In some embodiments, the communications network is a variety of different networks, such as an intranet and the Internet. The communications network includes wired and/or wireless communication channels. Each of the design house 720, the mask house 730, and the fab 750 interacts with one another and provides services to and/or receives services from one another. In some embodiments, two or more of the design house 720, the mask house 730, and the fab 750 coexist in a common facility and use common resources.

The design house 720 generates an integrated circuit design layout diagram 722. The integrated circuit design layout diagram 722 includes various geometrical patterns, such as the patterns shown in the layout 100 of FIG. 1. The geometrical patterns correspond to patterns of metal, oxide, or semiconductor layers that make up the various components of the integrated circuit device 760 to be fabricated. The various layers combine to form various integrated circuit features. For example, a portion of the integrated circuit design layout diagram 722 includes various integrated circuit features, such as an active region, a gate electrode, a source and drain, and conductive segments or vias of an interlayer interconnection, to be formed in a semiconductor substrate (e.g., a silicon wafer) and various material layers disposed on the semiconductor substrate. The design house 720 implements a proper design procedure to form the integrated circuit design layout diagram 722. The design procedure includes one or more of logic design, physical design, and place and route design. The integrated circuit design layout diagram 722 can be presented in one or more data files with information on the geometrical patterns. For example, the integrated circuit design layout diagram 722 can be expressed in a GDSII file format or DFII file format.

The mask house 730 includes data preparation 732 and mask fabrication 734. The mask house 730 uses the integrated circuit design layout diagram 722 to manufacture a mask 745 (or reticle 745) to be used for fabricating the various layers of the integrated circuit device 760. The mask house 730 performs mask data preparation 732, where the integrated circuit design layout diagram 722 is translated into a representative data file (“RDF”). The mask data preparation 732 provides the representative data file to mask fabrication 734. Mask fabrication 734 includes a mask writer that converts the representative data file to an image on a substrate, such as the mask 745 or a semiconductor wafer 753. The integrated circuit design layout diagram 722 can be manipulated by the mask data preparation 732 to comply with particular characteristics of the mask writer and/or requirements of the fab 750. In FIG. 7, data preparation 732 and mask fabrication 734 are illustrated as separate elements. In some embodiments, data preparation 732 and mask fabrication 734 can be collectively referred to as “mask data preparation.”

In some embodiments, data preparation 732 includes optical proximity correction (OPC), which uses lithography enhancement techniques to compensate for image errors, such as those that can arise from diffraction, interference, and other process effects. Optical proximity correction adjusts the integrated circuit design layout diagram 722. In some embodiments, data preparation 732 includes further resolution enhancement techniques (RET), such as off-axis illumination, sub-resolution assist features, phase-shifting masks, other suitable techniques, and combinations thereof. In some embodiments, inverse lithography technology (ILT) can be used, which treats optical proximity correction as an inverse imaging problem.

In some embodiments, data preparation 732 includes a mask rule checker (MRC) that checks whether the integrated circuit design layout diagram 722 has undergone optical proximity correction with a set of mask creation rules that include geometric and/or connectivity restrictions to ensure sufficient margins, to account for variability in semiconductor manufacturing processes. In some embodiments, the mask rule checker modifies the integrated circuit design layout diagram 722 to compensate for limitations during mask fabrication 734, which may undo part of the modifications performed by optical proximity correction to meet mask creation rules.

In some embodiments, data preparation 732 includes lithography process checking (LPC) that simulates processing that will be implemented by the fab 750 to fabricate an integrated circuit device 760. Lithography process checking simulates this processing based on the integrated circuit design layout diagram 722 to create a simulated manufactured device, such as the integrated circuit device 760. The processing parameters in the lithography process checking simulation can include parameters associated with various processes of the integrated circuit manufacturing cycle, parameters associated with tools used for integrated circuit manufacturing, and/or other aspects of the manufacturing process. Lithography process checking takes into account various factors, such as aerial image contrast, depth of focus (DOF), mask error enhancement factor (MEEF), and other suitable factors. In some embodiments, after a simulated manufactured device has been created by LPC and if the simulated device does not satisfy design rules, optical proximity checking and/or the mask rule checker are be repeated to further refine the integrated circuit design layout diagram 722.

In some embodiments, data preparation 732 includes additional features, such as a logic operation (LOP) to modify the integrated circuit design layout diagram 722 based on manufacturing rules. Additionally, the processes applied to the integrated circuit design layout diagram 722 during data preparation 732 may be executed in a different order than described above.

After data preparation 732 and during mask fabrication 734, a mask 745 is fabricated based on the modified integrated circuit design layout diagram 722. In some embodiments, mask fabrication 734 includes performing one or more lithographic exposures based on the integrated circuit design layout diagram 722. In some embodiments, an electron-beam (e-beam) or a mechanism of multiple e-beams are used to form a pattern on the mask 745 based on the modified integrated circuit design layout diagram 722.

The mask 745 can be formed by various technologies. In some embodiments, the mask 745 is formed using binary technology. In some embodiments, a mask pattern includes opaque regions and transparent regions. A radiation beam, such as an ultraviolet (UV) beam, can be used to expose the image sensitive material layer (e.g., photoresist) coated on a wafer. The radiation beam is blocked by the opaque region and transmits through the transparent regions. For example, a binary mask version of the mask 745 includes a transparent substrate (e.g., fused quartz) and an opaque material (e.g., chromium) coated in the opaque regions of the binary mask.

In some embodiments, the mask 745 is formed using a phase shift technology. In a phase shift mask (PSM) version of the mask 745, various features in the pattern formed on the phase shift mask are configured to have proper phase difference to enhance the resolution and imaging quality. For example, the phase shift mask can be an attenuated phase shift mask or an alternating phase shift mask.

The mask generated by mask fabrication 734 is used in a variety of processes. For example, the mask can be used in an ion implantation process to form various doped regions in the semiconductor wafer 753, in an etching process to form various etching regions in the semiconductor wafer 753, and/or in other suitable processes.

The fab 750 includes wafer fabrication 752. The fab 750 can include one or more manufacturing facilities for the fabrication of a variety of different integrated circuit products. In some embodiments, the fab 750 is a semiconductor foundry. For example, there may be a manufacturing facility for front-end fabrication of integrated circuit products (front-end-of-line (FEOL) fabrication), a second manufacturing facility to provide back end fabrication for the interconnection and packaging of the integrated circuit products (back-end-of-line (BEOL) fabrication), and a third manufacturing facility to provide other services for the foundry business.

The fab 750 uses the mask 745 fabricated by the mask house 730 to fabricate the integrated circuit device 760. In some embodiments, the semiconductor wafer 753 is fabricated by the fab 750 using the mask 745 to form the integrated circuit device 760. In some embodiments, the integrated circuit fabrication includes performing one or more lithographic exposures based on the integrated circuit design layout diagram 722. The semiconductor wafer 753 includes a silicon substrate or other appropriate substrate with material layers formed thereon. The semiconductor wafer 753 further includes doped regions, dielectric features, multilevel interconnects, and other suitable features.

The disclosed embodiments relate to optimizing layout cells in an IC layout design. As technology increases and the demand for scaled ICs grow, an increasing number of layout cells are required to fit in smaller IC layout designs, thus creating challenges for IC manufacturers. Embodiments of the present disclosure address this challenge, among others, by introducing layout cells with different configurations to optimize a circuit implementation in the IC layout design while minimizing the insertion of dummy fill structures by an electronic design automation tool.

Embodiments of the present disclosure describe a layout including a first semiconductor structure having a first channel with a first channel width and a second semiconductor structure having a second channel with a second channel width different from the first channel width. The first and second channels are can be in contact with each other.

Embodiments of the present disclosure describe a first semiconductor structure having a first gate with a first channel gate width and a second semiconductor structure having a second channel gate with a second channel gate width different from the first gate width. The first gate and the second gate can be in contact with each other.

Embodiments of the present disclosure describe a method including disposing a first diffusion region in a layout area and disposing a second diffusion region in the layout area. The first diffusion region can have a first diffusion region width and the second diffusion region can have a second diffusion region width different from the first diffusion region width. The method further includes depositing the second diffusion region such that the second diffusion region is connected to the first diffusion region.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first semiconductor structure having a first channel with a first channel width; and
a second semiconductor structure having a second channel with a second channel width different from the first channel width, wherein the first channel and the second channel are in contact with each other.

2. The structure of claim 1, wherein the first semiconductor structure comprises a high speed performance semiconductor device.

3. The structure of claim 1, wherein the second semiconductor structure comprises a passive semiconductor device.

4. The structure of claim 1, further comprising a dummy gate, the dummy gate having a dummy gate width.

5. The structure of claim 1, wherein a first gate of the first semiconductor structure is coupled to a second gate of the second semiconductor structure.

6. The structure of claim 1, wherein a first gate of the first semiconductor structure is decoupled to a second gate of the second semiconductor structure.

7. The structure of claim 1, wherein a gate of the second semiconductor structure is coupled to a reference voltage, and wherein the reference voltage is a voltage drain or a voltage source.

8. The structure of claim 1, wherein the first semiconductor structure comprises a first gate pitch between a first n-type channel and a first p-type channel and the second semiconductor structure comprises a second gate pitch between a second n-type channel and a second p-type channel.

9. The structure of claim 8, wherein a first channel height, the first channel width, a first channel gate width, and a first channel gate pitch are different from the second channel height, the second channel width, a second channel gate width, and a second channel gate pitch.

10. The structure of claim 4, wherein the dummy gate width is substantially similar to a first channel gate width of the first semiconductor structure or is substantially similar to a second channel gate width of the second semiconductor structure.

11. A structure, comprising:
a first semiconductor device cell having a first gate with a first gate width; and
a second semiconductor device cell having a second gate with a second gate width different from the first gate width, wherein the first gate and the second gate are in contact with each other.

12. The structure of claim 11, further comprising a dummy gate, wherein the dummy gate comprises dummy gate width.

13. The structure of claim 11, wherein the first semiconductor device cell comprises a first gate pitch between a first n-type channel and a first p-type channel and the second semiconductor device cell comprises a second gate pitch between a second n-type channel and a second p-type channel.

14. The structure of claim 13, wherein a first channel height of the first semiconductor device cell, a first channel width of the first semiconductor device cell, the first gate width, and the first gate pitch are different from a second channel height of the second semiconductor device cell, a second channel width of the second semiconductor device cell, the second gate width, and the second gate pitch.

15. The structure of claim 11, wherein the second semiconductor device cell gate is coupled to a reference voltage, wherein the reference voltage is a voltage drain or a voltage source.

16. A method, comprising:
disposing a first diffusion region in a layout area, wherein the first diffusion region has a first diffusion region width; and
disposing a second diffusion region in the layout area, wherein the second diffusion region has a second diffusion region width different from the first diffusion region width, wherein the second diffusion region is connected to the first diffusion region.

17. The method of claim 16, further comprising:
disposing a first gate structure over the first diffusion region, wherein the first gate structure has a third width; and
disposing a second gate structure over the second diffusion region adjacent to the first diffusion region, wherein the second gate structure has a fourth width different from the third width, wherein the second gate structure is connected to the first gate structure.

18. The method of claim 17, further comprising coupling at least one gate structure to a reference voltage, wherein the reference voltage is a voltage drain or a voltage source.

19. The method of claim 17, further comprising disposing a dummy fill structure in the layout area.

20. The method of claim 17, further comprising decoupling at least one first gate structure from at least one second gate structure.
